(19) United States
(12) Patent Application Publication
(10) Pub. No.: US 2007/0032040 A1
(43) Pub. Date: Feb. 8, 2007

(54) Method of manufacturing a multilayer semiconductor structure with reduced ohmic losses

(76) Inventor: Dimitri Lederer, RUE CAMILLE CALS 28, B-5030 (BE)

Correspondence Address: BACON & THOMAS, PLLC, 625 SLATERS LANE, FOURTH FLOOR, ALEXANDRIA, VA, 22314, US

(21) Appl. No.: 10/572,799

(22) PCT Filed: Sep. 27, 2004
(86) PCT No.: PCT/BE04/00137

§ 371 Date: Mar. 22, 2006

(51) Int. Cl. H01L 21/30; H01L 21/46

(52) U.S. Cl. 438/455

(57) ABSTRACT

The present invention provides a method of manufacturing a multilayer semiconductor structure featuring reduced ohmic losses with respect to standard multilayer semiconductor structures. The semiconductor structure comprises a high resistivity silicon substrate with resistivity higher than 3 KΩ.cm, an active semiconductor layer and an insulating layer in between the silicon substrate and the active semiconductor layer. The method comprises suppressing ohmic losses inside the high resistivity silicon substrate by increasing, with regard to prior art devices, charge trap density between the insulating layer and the silicon substrate. In particular this may be obtained by applying an intermediate layer in between the silicon substrate and the insulating layer, the intermediate layer comprising grains having a size, wherein the mean size of the grains of the intermediate layer is smaller than 150 nm, preferably smaller than 50 nm.

### TECHNICAL FIELD OF THE INVENTION

The present invention relates to a method of manufacturing a multilayer semiconductor structure comprising a high-resistivity (HR) silicon substrate, an active semiconductor layer and an insulating layer in between the silicon substrate and the active semiconductor layer. The present invention also relates to multilayer semiconductor structures thus obtained. More in particular the present invention relates to multilayer semiconductor structures suitable for being used in high frequency (HF—i.e., with operating frequency higher than 100 MHz), e.g. radio frequency (RF), integrated circuits, and a method of manufacturing them.

### BACKGROUND OF THE INVENTION

Multilayer semiconductor structures comprise a plurality of layers, of which at least some are made from different materials.

One example of such multilayer semiconductor structures are silicon-on-insulator (SOI) structures. An SOI comprises:
a thin (from a few tens of nm up to a few microns) active layer, featuring a low resistivity (of the order of a few Ω.cm, e.g. 5 to 30 Ω.cm); at the present state of the art the active layer is made from monocrystalline silicon, so that chip manufacturers can continue to use traditional manufacturing processes and equipment in the fabrication process,
a thick (several hundreds of microns) substrate, for example of silicon, and featuring a typical resistivity of 20 Ω.cm or larger,
a thinner (several hundreds of nm) insulating layer for electrically insulating the substrate from the active layer, for example a layer of SiO2 in between the substrate and the active layer.

The active layer is intended for receiving components, typically electronic or optoelectronic components.

FIG. 7 illustrates different steps of a method for manufacturing a conventional SOI wafer. First an oxide layer 70 is formed on a first silicon substrate 71 intended to be used as the active layer. A second silicon substrate 72, to be used as the thick substrate is then mounted on the oxide layer 70 by a thermal bonding method. Finally, the resultant structure is inverted, and an upper surface of the first silicon surface 71 is thinned, e.g. by grinding or a Smart Cut® process, down to a suitable predetermined thickness. The upper surface of the first silicon substrate 71 is then polished, thus forming a conventional SOI wafer.

In the context of semiconductor technology, SOI wafers present numerous advantages over conventional silicon bulk wafers and are currently widely used for both analog and digital applications.

However, for HF applications, it is well known that electric field lines generated by components in the active layer can cross the insulating layer despite its insulating effect, and penetrate into the substrate, leading to ohmic losses inside the substrate. Therefore, SOI wafers suitable to HF applications should have a level of HF ohmic losses, which is as low as possible.

It is usually admitted that ohmic losses are negligible if the substrate resistivity is higher than 3 kΩ.cm. Such substrates are called high resistivity (HR) substrates. Currently manufactured HR silicon substrates can have a resistivity of about 10⁴ Ω.cm, as compared to about 20 Ω.cm for standard-resistivity substrates that are typically used in CMOS technology. Using HR substrates can therefore significantly reduce losses and coupling (cross-talk) in HF applications. HR substrates are used to fabricate HR SOI wafers.

However, one major drawback of HR SOI wafers is their decreased effective resistivity, in particular for high frequency applications. The effective resistivity is defined in this text as the actual value of the resistivity that is seen by HF circuits fabricated above the insulating layer, either within the active layer or at a higher metal level in current standard CMOS processes.

For instance, it has been shown that the effective resistivity of a HR SOI wafer with a thickness of the insulating layer of 150 nm and a density of fixed charges Qₒₓ in the insulating layer as low as 10¹⁰/cm² could lead to an effective resistivity value of around 300 Ω.cm, which is more than one order of magnitude lower than the substrate resistivity. This, of course, considerably increases HF ohmic losses and makes such substrates unsuitable for HF applications.

It has also been shown that multilayer standard CMOS processes with a several micron thick insulating layer could lead to very high values of Qₒₓ (of the order of a few 10¹¹/cm²). In this case, despite the high thickness of the insulator, the effective resistivity was also found to be more than one order of magnitude lower than the substrate resistivity.

It is desired that multilayer structures as intended by the present invention have ohmic losses in the substrate that are as low as possible, These losses are indeed disadvantageous as they deteriorate the electrical performance of the multilayer structure in particular for high frequency applications.

### SUMMARY OF THE INVENTION

It is an object of the present invention to provide a method of manufacturing multilayer semiconductor structures of the type mentioned above, in which electrical losses are reduced, preferably as much as possible, and to provide such multilayer semiconductor structures themselves, e.g. as made by the method, in which the electrical losses are reduced or minimised, preferably at high frequency applications.

It is furthermore an object of the present invention to provide such multilayer structures which are thermodynamically stable.

The above objective is accomplished by a method and device according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

In a first aspect, the present invention provides a method of manufacturing of a multilayer semiconductor structure comprising a high resistivity silicon substrate with resistivity higher than 3 kΩ.cm, an active semiconductor layer and an insulating layer in between the silicon substrate and the active semiconductor layer. The method comprises suppressing ohmic losses inside the high resistivity silicon substrate by modifying, e.g. increasing with regard to prior art devices, charge trap density between the insulating layer and the silicon substrate and/or by modifying the electrical charges in the insulating layer in order to minimise the electrical losses inside the substrate.

The modification of the charge trap density aims at increasing the charge trap density at the interface between the insulating layer and the substrate. This means that the charge trap density of multilayer semiconductor structures manufactured with a method according to the present invention is higher than what it would be at the interface between substrate and insulator if no special measures according to the present invention were taken.

The modifications of the electrical charges in the insulating layer aim at decreasing the electrical charges in the insulating layer.

Modifying the charges in the insulating layer may be performed by adjusting the characteristics of an implantation performed in the active layer before the insulated active layer is bonded to the substrate. The amounts of impurities may be changed in order to modify the charges in the insulating layer. Alternatively, the charges in the insulating layer may be modified by adjusting the parameters of a thermal oxidation performed on the active layer in order to generate at its surface an insulating layer which will form, after bonding to a substrate, the insulating layer of the multilayer structure to be formed. The thermal oxidation may be a manufacturing step for manufacturing an oxide layer in a Smart Cut® type process. The parameters to be adjusted may comprise one or more of, but are not limited to, temperature (in absolute value) and/or temperature changes (in particular ramp characteristics of the temperature), gas composition, annealing time. The charges in the insulating layer may be modified by adjusting the parameters of a thermal treatment which is applied to the multilayer structure after it has been formed. The thermal budget of such thermal treatment may be adjusted so as to reduce the charges in the insulating layer of the structure.

Increasing charge trap density according to the present invention may comprise applying an intermediate layer intended to be in contact with the substrate and with the insulating layer. The intermediate layer is made of a material which causes, by its connection to the substrate material, an increase of the charge trap density. The intermediate layer may be made of nitride oxide.

Increasing charge trap density may comprise treating of the surface of the substrate, e.g. a controlled damaging of the surface of the substrate, for example modifying its roughness by etching.

Increasing charge trap density according to the present invention may comprise applying an intermediate layer in between the silicon substrate and the insulating layer, the intermediate layer comprising grains having a size, wherein the mean size of the grains of the intermediate layer is smaller than 150 nm, preferably smaller than 50 nm, e.g. between 20 nm and 40 nm.

The intermediate layer may have a charge trap density of at least 10¹¹/cm²/eV. The lower limit on the charge trap density depends on the number Qₒₓ of fixed charges in the insulating layer if this number is high, i.e. e.g. 10¹¹ cm² or higher, the charge trap density Dᵢₜ must be at least 10¹²/cm²/eV, if the number Qₒₓ of fixed charges in the insulating layer is low, i.e. e.g. 10¹¹/cm² or lower, it is sufficient if the charge trap density Dᵢₜ is 10¹¹/cm²/eV.

Applying an intermediate layer may comprise applying any of an undoped or lightly doped silicon layer, e.g. with a doping level lower than 3. 10¹²/cm³, an undoped polysilicon layer, a germanium layer, an undoped polygermanium layer or a poly-SiGe silicon carbide layer in between the silicon substrate and the insulating layer. It has been proven by the inventors that the use of such intermediate layer diminishes losses associated with the multilayer structure of the present invention, especially at frequencies above 100 MHz, thanks to the efficiency of the generated charge traps which aid in capturing free charge carriers.

Applying a polysilicon layer may comprise depositing amorphous silicon on the silicon substrate and crystallizing the amorphous silicon so as to form the polysilicon layer. Crystallizing may for example comprise thermal annealing, rapid thermal annealing (RTA) or laser crystallisation.

The intermediate layer has an RMS (root mean square) roughness of its outer surface, and preferably, according to the present invention the RMS roughness of the intermediate layer has an average value smaller than or equal to 0.5 nm, in order to enable the bonding of an insulator-passivated silicon substrate and the intermediate layer, such as for example an intermediate-layer covered HR silicon substrate. This means that the intermediate layer at the same time aids in reducing ohmic losses of the multilayer structure, and in obtaining a surface roughness that is low enough to ease bonding to other layers without the need for any planarisation such as e.g. chemical-mechanical polishing (CMP).

A method according to the present invention may comprise bonding an intermediate layer-covered, e.g. polysilicon-covered, high resistivity silicon substrate to an insulator-passivated semiconductor substrate. The intermediate layer is applied to the high resistivity silicon substrate prior to bonding the silicon substrate to the insulating layer, so as to bond the intermediate layer to the insulating layer. Prior to bonding the high resistivity silicon substrate to the insulator-passivated semiconductor substrate, a surface oxidation of the intermediate layer may be performed so as to form an insulator layer of a few nanometre thickness at the surface of the intermediate layer. This leads to an insulator-insulator bonding afterwards.

Alternatively, a method according to the present invention may comprise providing an intermediate layer on an insulator-passivated semiconductor substrate, and bonding this to a high-resistivity silicon substrate.

According to an embodiment of the present invention, the intermediate layer may have a thickness of at least 100 nm, preferably between 100 and 450 nm, and more preferred between 200 nm and 300 nm.

A method according to the present invention may furthermore comprise introducing charge traps at the insulator-semiconductor substrate interface to a level sufficiently high as to reach a value of effective resistivity higher than 5 kΩ.cm, preferably higher than 10 kΩ.cm. This level of charge trap density is at least 10¹¹/cm²/eV.

According to an embodiment of the present invention, the density of charge traps remains higher than or equal to 10¹¹/cm²/eV after a standard CMOS process is performed on the multilayer structure. Also the value of the multilayer structure effective resistivity remains higher than 5 kΩ.cm, preferably higher than 10 kΩ.cm after a standard CMOS process is performed on the structure.

The active semiconductor layer has a low resistivity, e.g. of the order of to 30 Ω.cm, in order to allow good interaction of the electrical components which will be provided on or in this layer. This layer may be made from at least one of Si, Ge, SiₓGe_{y}, SiC, InP, GaAs or GaN. The active semiconductor layer may comprise a stack of layers, at least one layer being made of Si, Ge, SiₓGe_{y}, SiC, InP, GaAs or GaN.

The insulating layer may be formed of at least one of an oxide, a nitride, Si₃N₄, porous insulating material, low-k insulating materials, polymers. The insulating layer may be formed of a stack of layers, at least one layer being made of an oxide, a nitride, Si₃N₄, porous insulating material, low-k insulating materials, polymers.

In a second aspect, the present invention provides a multilayer structure featuring reduced ohmic losses with respect to prior art multilayer structures, in particular for high frequency (HF) applications, i.e. for applications having an operating frequency higher than 100 MHz. The multilayer structure comprises a high resistivity silicon substrate with a resistivity higher than 3 kΩ.cm. This high resistivity of the substrate, which will be supporting other layers of the multilayer structure according to the present invention, already aims at reducing the losses associated with the multilayer structure. The multilayer structure furthermore comprises an active semiconductor layer and an insulating layer in between the silicon substrate and the active semiconductor layer. According to the present invention, the multilayer structure furthermore comprises an intermediate layer in between the high resistivity silicon substrate and the insulating layer. The intermediate layer comprises grains having a size, wherein the mean size of the grains of the intermediate layer is smaller than 150 nm, preferably smaller than 50 nm, e.g. between 20 nm and 40 nm.

The intermediate layer may have a charge trap density of at least 10¹¹/cm²/eV, preferably at least 10¹²/cm²/eV. The effective resistivity of the multilayer structure of the present invention is higher than 5 kΩ.cm, preferably higher than 10 kΩ.cm.

In a multilayer structure according to the present invention, the intermediate layer may comprise any of an undoped or lightly doped silicon layer, an undoped polysilicon layer, a germanium layer, an undoped polygermanium layer or a poly-SiGe silicon carbide layer.

The intermediate layer, for example the polysilicon layer, may have a roughness with an average value smaller than or equal to 0.5 nm. In this case, a large number of small crystals are present in the intermediate layer, and consequently a high number of grain boundaries, which function as charge traps.

The active semiconductor layer has a low resistivity, e.g. of the order of 5 to 30 Ω.cm, in order to allow good interaction of the electrical components which will be provided on or in this layer. This layer may be made from at least one of Si, Ge, SiₓGe_{y}, SiC, InP, GaAs or GaN. The active semiconductor layer may comprise a stack of layers, at least one layer being made of Si, Ge, SiₓGe_{y}, SiC, InP, GaAs or GaN.

The insulating layer may be formed of at least one of an oxide, a nitride, Si₃N₄, a porous insulating material, a low-k insulating material such as a low-k oxide, a high-k dielectric or a polymer. The insulating layer may be formed of a stack of layers, at least one layer being made of an oxide, a nitride, Si₃N₄, a porous insulating material, a low-k insulating material, a high-k dielectric or a polymer.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 illustrates a multilayer structure according to an embodiment of the present invention.

FIG. 2 is a graph illustrating the transverse conductance of a metallic Coplanar Waveguide (CPW) made on multilayer structures having increasing charge trap densities at the interface between substrate and insulating layer.

FIG. 3 illustrates different steps of a method for manufacturing multilayer structures according to an embodiment of the present invention.

FIG. 4 illustrates different steps of another method for manufacturing multilayer structures according to a further embodiment of the present invention.

FIG. 5 is a SEM picture of polysilicon deposited at 625° C.

FIG. 6 shows SEM pictures of amorphous silicon (a) as deposited at 525° C. and (b) annealed at 900° C. for 2 minutes by Rapid Thermal Annealing (RTA).

FIG. 7 illustrates different steps of a method for manufacturing a conventional SOI wafer.

FIG. 8 is a graph illustrating the transverse conductance of a metallic Coplanar Waveguide (CPW) made on multilayer structures having increasing fixed charges in the insulating layer.

FIG. 9 is a schematic representation illustrating the principle of a measurement method for measuring electrical losses in a multilayer structure such as a multilayer structure according to the present invention. The multilayer structure is represented in cross-section, and the schematic drawing represents at its right hand side a representation of an equivalent electrical circuit.

FIG. 10 illustrates electrical losses of multilayer structures measured in function of frequency.

FIGS. 11(a) and (b) show AFM pictures illustrating RMS (root mean square) roughness for RTA-crystallized amorphous silicon deposited at 525° C. and for polysilicon deposited at 625° C.

In the different figures, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

The invention will now be described by a detailed description of several embodiments of the invention. It is clear that other embodiments of the invention can be configured according to the knowledge of persons skilled in the art without departing from the true spirit or technical teaching of the invention, the invention being limited only by the terms of the appended claims.

In general, the structures to which the present invention relates are typically structures in which the active layer has an electrical resistivity that is substantially lower than the resistivity of the substrate.

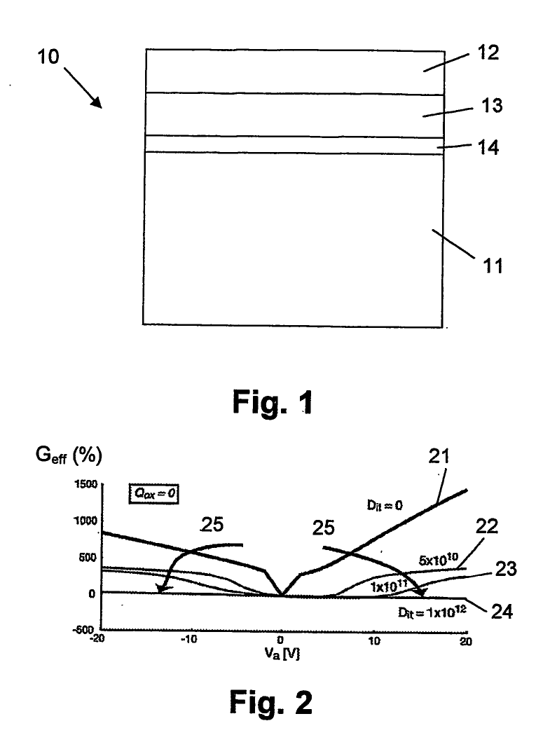

As an example, a multilayer structure 10 of the type SOI is considered, as illustrated in FIG. 1. This multilayer structure 10 comprises a silicon substrate 11, an active layer 12 and an insulating layer 13 between the silicon substrate 11 and the active layer 12. According to the present invention, a standard HR SOI structure as described above is modified so as to influence, especially to increase with respect to such standard HR SOI structure, the density of carrier traps between the insulating layer 13 and the substrate 11 by at least two orders of magnitude. Such an increase can reduce or minimise the losses associated with this multilayer structure 10.

The inventors have determined, based on simulations and experiments, that it is possible to reduce the losses associated with the structure
by reducing the electrical charges in the insulating layer of a multilayer structure. With respect to this aspect, the inventors have shown the influence of the value of a parameter Qₒₓ on the electrical losses in the substrate, the parameter Qₒₓ corresponding to the electrical charges associated with the insulating layer of the structure, i.e. the buried insulating layer in case of an SOI.
and/or by increasing the charge trap density, and this more particularly at the interface between the insulating layer of the multilayer structure and the substrate. With respect to this aspect, the inventors have shown the influence of a parameter Dᵢₜ on the electrical losses in the substrate, the parameter Dᵢₜ corresponding to the charge trap density.

The present invention elaborates on both aspects, with regard to the parameter Qₒₓ and with regard to the parameter Dᵢₜ, which may be applied according to the present invention separately or in combination in order to obtain a multilayer structure with reduced ohmic losses with regard to prior art multilayer structures, i.e. a multilayer structure having an effective resistivity of at least 5 kΩ.cm, and preferably at least 10 kΩ.cm.

Before presenting the results of numerical simulations and experiments carried out by the inventors, the principles used in a method for measuring the losses during the simulations and experiments will be shortly explained.

The method of measuring losses is generally known as “measurement of losses by coplanar waveguide”. It allows measuring the losses up to a certain depth in function of the spreading of the electromagnetic fields in the substrate. This depth depends on the spacing between the conductors, on the frequency, on the resistivity of the substrate and on the thickness of the insulating layer.

The measurement method uses the following steps for each multilayer structure to be characterised, the multilayer structure comprising at least a substrate 11, an insulating layer 13 and an active layer 12:
Preparation of the structure.
Selective etching of the active layer 12 of the structure, the etching being so as to stop on the insulating layer 13 consisting of a buried oxide in case of an SOI.
Deposition of a full layer of electrically conductive metal on the structure, on top of the buried oxide.
Selective dry etching of the deposited metal for forming test patterns, in the present case conductive parallel metallic lines forming coplanar waveguides (CPW), there being a central metallic line between the parallel metallic lines.
Application of an electrical signal on the central metallic line. This signal comprises a superposition of a continuous voltage and an alternating voltage of low amplitude. This combined voltage is applied to the line and the following parameters can be determined:
   the amplitude V_{A} of the continuous component,
   the frequency f of the alternating component.

Superposing a continuous voltage component and an alternating voltage component during the measurements illustrates the tremendous effect of a low resistivity layer present under the interface between the insulating layer and the substrate. As will be explained later, this low resistivity layer is generated underneath the central metallic line by the application of the continuous component.
Calculation of the losses α.

The losses α comprise a first part α_{COND} which are losses in the conductors and a second part α_{SUB} which are losses in the layers located underneath the active layer previously etched. The losses α_{SUB} in the layers located underneath the active layer are extracted from the measurement of emitted, transmitted and received power waves at the extremities of the CPW, and thus the total losses a measured, and an estimation of α_{COND} which is considered to be fixed for a given frequency of the applied signal.

The low resistivity layer generated underneath the central metallic line is substantially influenced by the parameters Qₒₓ and Dᵢₜ. It is thus by the concentration of charge carriers and the global volume of the low resistivity layer (in particular determined by its thickness) that the effect of Qₒₓ and Dᵢₜ is felt.

The losses measured during the application of the above measurement method allow extraction of the effective resistivity of the structure. This effective resistivity is directly related to the losses in the layers located underneath the active layer.

In a first aspect of the present invention, it has been demonstrated that decreasing the number of fixed charged in the oxide (referred to as Qₒₓ) can be efficient to improve the effective resistivity of HR multilayer structures, e.g. HR SOI wafers.

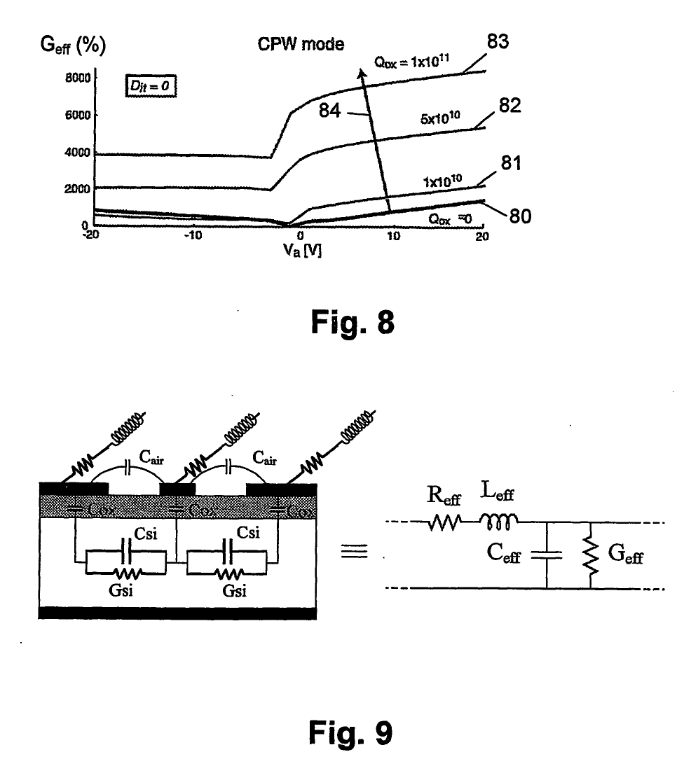

Results of simulations are shown in FIG. 8, which shows the transverse conductance of a metallic Coplanar Waveguide (CPW) made on multilayer structures having increasing fixed charges in the insulating layer.

The plots in this drawing are obtained by a simulation model allowing calculation of the linear parallel conductance (G_{eff}) of coplanar waveguides realised on a structure.

Referring to FIG. 9, coplanar waveguides realised on a multilayer structure are shown, as well as a distributed equivalent circuit (right hand side).

The propagation coefficient γ associated with the coplanar waveguide is of the following form:
γ=(α_{COND}+α_{SUB})+jβ=\sqrt{(R_{eff}+jωL_{eff})·(G_{eff}·jωC_{eff})}

The losses α_{SUB} associated with the substrate are directly proportional to G_{eff} at high frequencies, i.e. at frequencies of 100 MHz or higher.

Indeed, the losses α_{SUB} are equal to └0.5*G_{eff}*(L_{eff}/C_{eff})^{0.5}┘, L_{eff} and C_{eff} corresponding respectively to the effective inductance and the effective linear capacitance of the coplanar structure represented in FIG. 9.

For a given structure, the higher the value of the parameter G_{eff}, the higher the losses associated with the structure (and vice versa).

The above model is used by the Atlas® simulation software of Silvaco, Calif., US. This model allows to take into account the different dimensional parameters of the coplanar waveguide:
geometry of the metallic lines formed on the multilayer structure for measuring the losses,
thickness of the insulating layer (buried layer) of the multilayer structure,
amplitude V_{A} of the continuous voltage component applied to the metallic lines, taking into account the amplitude and the frequency of the alternating component.

Furthermore, this model takes into account the parameters Dᵢₜ and Qₒₓ when calculating G_{eff}.

FIG. 8 shows four graphs 80, 81, 82, 83, corresponding to four different structures associated with four different values of the parameter Qₒₓ, as shown in the drawing. Each of the graphs illustrates the relative evolution, with regard to a reference point, of the electrical losses in the structure (via the parameter G_{eff}, which is, as explained above, directly related to the losses), and this in function of a voltage with amplitude V_{A} which would be applied to a conductor of the structure when measuring the losses according to a method as described below.

The reference point is fixed at a value of G_{eff} obtained for V_{A}=Qₒₓ=Dᵢₜ=0.

Graph 80 corresponds to a multilayer structure of which the value of Qₒₓ is zero.

Graphs 81, 82 and 83 each correspond to different multilayer structures, of which the insulating layers present values for Qₒₓ different from 0, and increasing from the multilayer structure associated with graph 81 (for which the charge of the insulating layer equals 10¹⁰/cm²) to the multilayer structure associated with graph 83 (for which the charge of the insulating layer equals 10¹¹/cm²).

The arrow 84 in FIG. 9 reflects the increase of Qₒₓ between the multilayer structures associated with the different graphs.

FIG. 9 illustrates that an increase of the value of Qₒₓ leads to an increase of the losses of the multilayer structure.

The influence of the parameter Qₒₓ, and thus the influence of the charge of the insulating layer is explained hereinafter. The charge in the insulating layer is a positive charge, which thus has a tendency to attract at the interface between the insulating layer and the high resistivity substrate negative mobile charges (electrons). These electrons accumulate at the interface and form a superficial low resistivity layer, which thus increases the global electrical losses in the substrate.

When using the method for measurement of losses as mentioned above, by applying to the central conductor a slightly negative voltage V_{A}, these electrons are temporarily pushed away underneath the central conductor, and move farther away from the surface. This part of the interface between the insulating layer and the substrate thus becomes more resistive, and the measured losses decrease. If now the amplitude V_{A} is made still more negative, the mobile positive charges will be attracted towards the interface and will thus locally decrease its resistivity. It is thus for a negative voltage V_{OPT} that the electrical losses in the substrate are minimal. This offset of the minimum of the losses is illustrated in FIG. 8. The higher the value of Qₒₓ, the more the value of V_{OPT} is offset towards negative voltage values.

In a same way, for an important value of Qₒₓ, the presence of electrons at the interface between the insulating layer and the substrate leads to an increase of the losses (even at V_{OPT}, which is the voltage for which the electrons attracted as described above at the interface between the insulating layer and the substrate are not present underneath the central conductor to which a voltage VA is applied, but are present at other location of the interface).

An increase of the value of Qₒₓ between two identical structures thus induces, as shown in FIG. 8, an increase of the losses and an offset of the optimal value V_{OPT} (corresponding to minimal losses) of the amplitude V_{A} of the continuous component towards negative potentials.

In a second aspect of the present invention, it is demonstrated that increasing the trap density (referred to as Dᵢₜ) between the insulator and the substrate can be efficient to improve the effective resistivity of HR multilayer structures, e.g. HR SOI wafers. Indeed, such traps play an important role in capturing free carriers, making them unable to react to HF electrical fields and thus suppressing their contribution to HF ohmic losses. With. HF electrical fields is meant electrical fields having an operating frequency higher than 100 MHz.

According to an embodiment of the present invention, the density of carrier traps between the insulating layer 13 and the substrate 11 is increased by providing a high resistivity layer 14, i.e. having a resistivity of at least 3 kΩ, containing a high trap density, i.e. a trap density of at least 10¹¹/cm²/eV, preferably at least 10¹²/cm²/eV, as an intermediate layer between the substrate 11 and the insulating layer 13, as illustrated in FIG. 1. This high resistivity layer 14, could for example be made from undoped polysilicon, undoped polygermanium, or poly-SiGe silicon carbide. It has been proven that providing such intermediate layer 14 between the substrate 11 and the insulating layer 13 diminishes the losses associated with the multilayer structure 10, especially at high frequencies thanks to the efficiency of the traps to capture free carriers.

As already mentioned, and as will be illustrated in detail, the density Dᵢₜ of charge traps has an influence on the losses of the multilayer structure.

FIG. 2 shows four curves 21, 22, 23, 24 corresponding to four different structures, each curve showing linear parallel conductance G_{eff}, which is, as explained above, directly related to the losses, in function of applied DC voltage amplitude V_{A}, the alternating component having a frequency f of 10 GHz and an amplitude of less than 100 mV. Each structure is associated with a different value for the charge trap density Dᵢₜ between the insulating layer 13 and the substrate 11. A first structure, corresponding to curve 21, has a charge trap density Dᵢₜ equal to 0; a second structure, corresponding to curve 22, has a charge trap density Dᵢₜ of 5×10¹⁰/cm²/eV; a third structure, corresponding to curve 23, has a charge trap density Dᵢₜ of 10¹¹ cm²/eV; and a fourth structure, corresponding to curve 24, has a charge trap density Dᵢₜ of 10¹²/cm²/eV. The arrows 25 at each side of the minimum of the three curves 21, 22, 23 reflect the increase of Dᵢₜ between the different structures. Curves 21, 22 and 23 each present a minimum in the neighbourhood of the abscissa 0 Volts (thus corresponding to a voltage for which the losses are minimal which is substantially identical for each of the cases).

It can be seen that an increase of charge trap density Dᵢₜ results in a decrease of the losses associated with the multilayer structure. It can be seen from FIG. 2 that the multilayer structure having the largest value for the charge trap density Dᵢₜ is the one with the lowest losses. The losses of this structure correspond to an effective resistivity of the order of 4000 Ω.cm, which makes the losses associated with the substrate negligible with respect to the losses associated with the metallic conductors. Indeed, the total losses a being equal to the sum of the losses α_{COND} and α_{SUB}, as α_{SUB} goes to zero, α becomes equal to α_{COND}.

It can also be seen that an increase of charge trap density Dᵢₜ decreases the influence of the amplitude V_{A} of the continuous component of the voltage applied to the central metallic line of the structure.

The influence of the parameter Dᵢₜ on the losses can be explained as follows. The parameter Dᵢₜ characterises the density of traps located between the insulating layer 13 and the substrate 11, and originating from substrate contaminations or being any other trap suitable for capturing a charge carrier, i.e. a hole or an electron. It has to be noted that the charge trap density value Dᵢₜ defines the number of charge traps per surface unit of the interface. This allows comparing values of Dᵢₜ independent of the layer thicknesses. In reality, however, the charge traps are located not only at the surface but also in the bulk, and this particularly in case microcrystals, each having a grain boundary, form the intermediate layer. Values for Dᵢₜ as presented in literature usually take into account the number of charge traps present at the interface, and not in the bulk.

An important charge trap density at the interface between the insulating layer and the substrate will have a tendency to be inverse to the influence mentioned above with regard to the influence of an increase or charges in the insulating layer. Indeed, an important charge trap density at the interface leads to absorption of part of the electrons forming the superficial layer, which are gathered at the interface and which decrease the resistivity (and thus increase the electrical losses) of the multilayer structure. The higher the charge trap density, the more this effect, which thus decreases the losses, is important.

The effect of the continuous voltage component which attracts near the interface negative (electrons) or positive (holes) charges, depending on the polarity of this voltage, is reduced by a more important charge trap density: in this case indeed, a part of the mobile charges attracted towards the interface by the continuous voltage component are trapped so as to have no impact on HF losses.

It is to be noted that the effect of an increase of the charge trap density has the same influence for positive or negative DC voltage components, as can be seen from FIG. 2.

A particular treatment for obtaining an increase in charge trap density Dᵢₜ between the substrate 11 and the insulating layer 13 of a multilayer structure 10 according to an embodiment of the present invention is to introduce at that location a polysilicon layer as a high resistivity layer containing a high trap density.

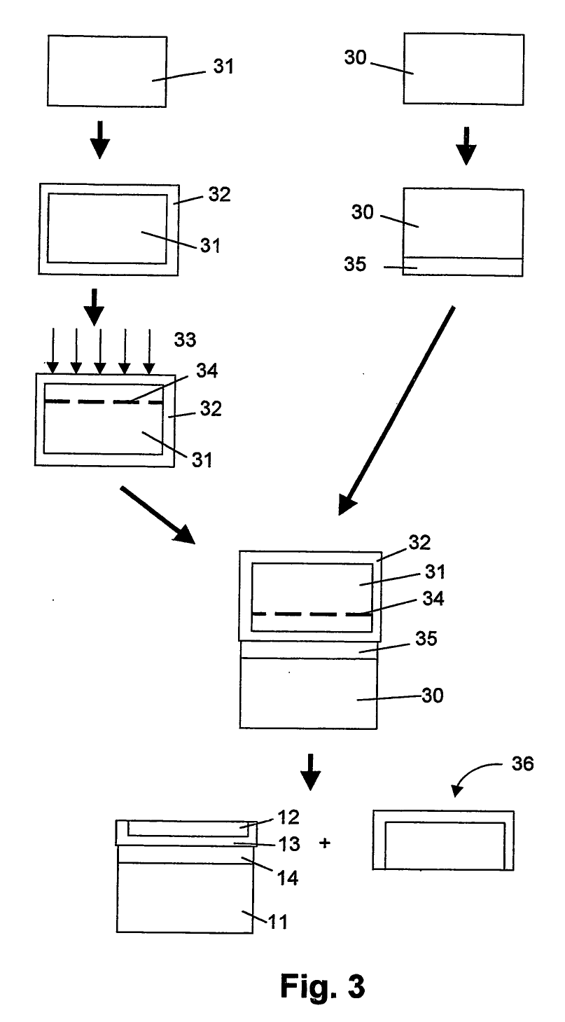

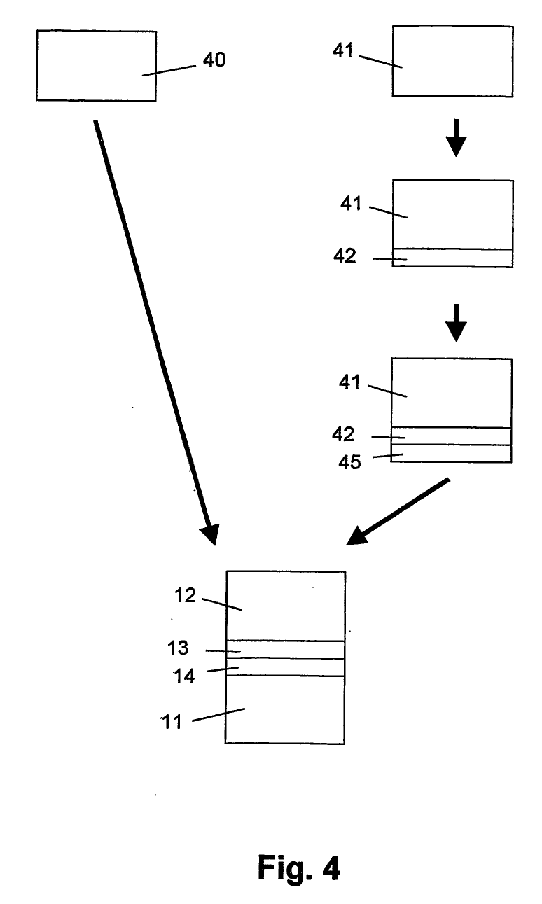

According to an embodiment of the present invention, the multilayer structure 10 may be obtained by a Smart Cut process as follows, and as illustrated in FIG. 3. A first high resistivity silicon wafer 30, having a resistivity of at least 3 kΩ.cm is provided, as well as a second wafer 31 which is made from a material of which the active layer 12 will be made, eg. at least one of Si, Ge, SiₓGe_{y}, SiC, InP, GaAs or GaN, or a stack of layers of which at least one is made from Si, Ge, SiₓGe_{y}, SiC, InP, GaAs or GaN. An insulating layer 32 is provided on the second wafer 31, e.g. the second wafer 31 may be oxidised, or an insulating layer may be deposited, so as to form the insulating layer 32 at at least one side of the second wafer 31. The insulating layer 32 may be made from any suitable material, such as one or a combination of dielectrics such as SiO2, Al2O3, AlN, Si3N4, titanates, porous insulating materials, low-k insulating materials. Smart cut ion implantation 33 then induces formation of an in-depth weakened layer 34 in the second wafer 31.

A high resistivity layer 35 containing a high trap density is then deposited on the first substrate 30. This layer 35 may for example be any of the following: undoped or lightly doped silicon, undoped polysilicon, germanium, undoped polygermanium, poly-SiGe silicon carbide, but is not limited thereto. This layer can then be oxidized but does not need to be.

The particular case of an undoped amorphous silicon layer 35 deposition is considered hereafter.

Thereafter, the thus prepared first and second wafers 30, 31 are cleaned and bonded to each other. By the Smart Cut process, a cleavage is carried out at the mean ion penetration depth, and part 36 of the second substrate 31 is taken away, so that only an insulating layer 13, an active layer 12 and an amorphous silicon layer 35 are left on top of the first substrate 30.

The amorphous silicon layer 35 is crystallized so as to form a large number of small grains, i.e. having a size smaller than 150 nm, preferably smaller than 50 nm, e.g. between 20 nm and 40 nm, thus forming a HR trap-rich polysilicon layer 14. This crystallization may be done by any suitable crystallisation method, e.g. by annealing, by rapid thermal annealing (RTA), or by laser crystallisation. This crystallization step can be performed before, during or after the bonding of the prepared first and second wafers, 30 and 31. It is an advantage of the present invention that an RMS roughness with an average value smaller than or equal to 0.5 nm is obtained, so that the polysilicon layer does not need to be flattened or planarised, e.g. by chemical-mechanical polishing (CMP), before a bonding between the polysilicon-covered first substrate 30 and the insulator-passivated and cleavage-prepared second substrate 31 can be carried out.

Alternatively, according to a further embodiment of the present invention, the multilayer structure 10 may be obtained as follows.

A first silicon wafer 40 is provided, as well as a second wafer 41 which is made from a material of which the active layer 12 will be made, eg. at least one of Si, Ge, SiₓGe_{y}, SiC, InP, GaAs or GaN, or a stack of layers of which at least one is made from Si, Ge, SiₓGe_{y}, SiC, InP, GaAs or GaN. An insulating layer 42 is provided on the second wafer 41, e.g. the second wafer 41 may be oxidised, or an insulating layer may be deposited, so as to form the insulating layer 42 at at least one side of the second wafer 41. The insulating layer 42 may be made from any suitable material, such as one or a combination of dielectrics such as e.g. SiO2, Al2O3, AlN, Si3N4, titanates, porous insulating materials, or low-k insulating materials.

A high resistivity layer 45, having a resistivity of at least 3 kΩ.cm, and having a grain size smaller than 150 nm, preferably smaller than 50 nm, is then provided on the insulated second wafer 41. This layer 45 may for example be any of the following: undoped or lightly doped silicon, undoped polysilicon, germanium, undoped polygermanium, poly-SiGe silicon carbide, but is not limited thereto. This layer may for example be formed of an amorphous silicon layer which is crystallised so as to form a large number of small grains, thus forming a charge trap-rich intermediate layer. As above, crystallization may be done by any suitable crystallisation method, e.g. by annealing, by rapid thermal annealing (RTA), or by laser crystallisation. This crystallization step can be performed before, during or after the bonding of the prepared first and second wafers, 40 and 41.

Thereafter, the thus prepared first and second wafers 40, 41 are cleaned and bonded to each other.

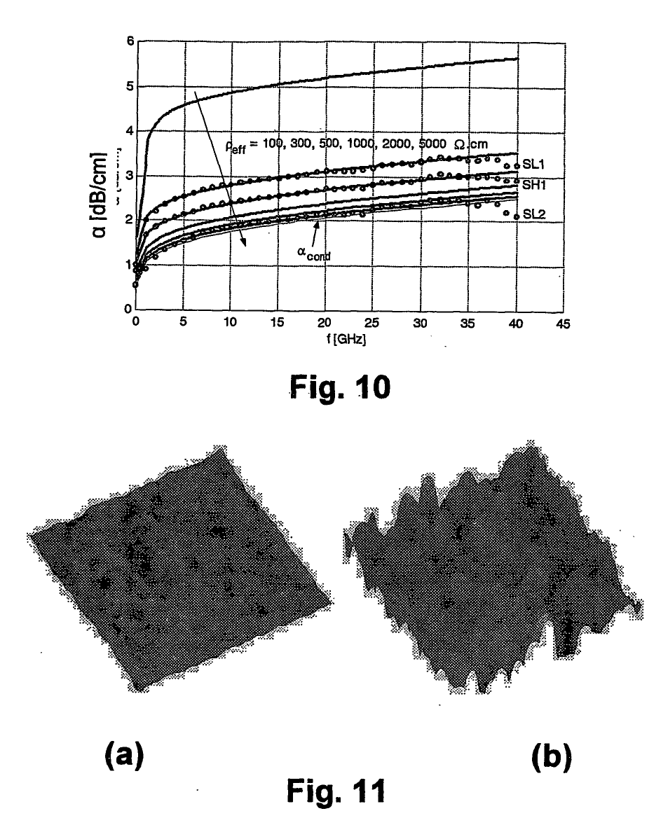

FIG. 10 illustrates electrical losses of multilayer structures measured in function of frequency. The graphs of FIG. 10 represent the evolution of the losses for the amplitude of the continuous voltage component V_{A}=0 V, in function of the frequency, for three SOI structures obtained by a Smart Cut® process, and presenting different values for Qₒₓ and Dᵢₜ.

Table 2 hereinbelow represents values for Qox and Dit for each of the three structures SL1, SL2, SH1.

TABLE 2

| Name of the | | |
|---|---|---|
| structure | Qₒₓ [#/cm²] | Dᵢₜ [#/cm²/eV] |
| SL1 | ˜1e10 | negligible |
| SL2 | ˜1e10 | ˜1e11 |
| SH1 | ˜1e10 with | negligible |
| | Q_{ox,SH1} > Q_{ox,SL1} | |

The dotted graphs in FIG. 10 correspond to simulated losses of CPW realised on identical structures, except for the resistivity ρ_{eff} of the substrate of the multilayer structures, which varies from 100 Ω.cm (highest graph) to 5000 Ω.cm (lowest graph), the values for the resistivity ρ_{eff} increasing as indicated by the arrow in FIG. 10, and with the values as mentioned. These graphs show that the higher the resistivity ρ_{eff}, the lower the theoretical losses. It is to be noted that the theoretical losses encompass the losses associated with the metallic conductors (corresponding to the lowest graph of FIG. 10, in full line) and the losses in the substrate.

FIG. 10 also illustrates that the multilayer structure with the highest value for Dᵢₜ is the one that shows the lowest losses. The losses of this structure correspond to an effective resistivity of the order of 4000 Ω.cm, which makes the losses associated with the substrate negligible with respect to the losses associated to the metallic lines (the total losses a being equal to the sum of the losses α_{SUB} and α_{COND}, and as α_{SUB} goes to 0, α equals α_{COND}).

The multilayer structures showing low values for Qₒₓ, but negligible values for Dᵢₜ show losses corresponding to substrate resistivity values of only 300 and 500 Ω.cm.

According to the present invention, the charge trap density and/or the value of charges in the insulating layer of a multilayer structure are changed in order to maximise the effective resistivity of said multilayer structure.

Additional simulations performed with Atlas® have enabled the inventors to quantify the minimum level of required charge trap density Dᵢₜ to provide robust wafers. These simulations have shown, that trap densities of the order of 10¹¹/cm²/eV, preferably 10¹²/cm²/eV are high enough to get rid of all parasitic conduction paths near the substrate interface even if the insulating layer 13 is characterised by concentration Qₒₓ of charge carriers in the insulating layer 13 as high as a few times 10¹¹/cm². Such a high value of Qₒₓ is currently reached in multilayer standard CMOS processes and is expected to increase even further in future CMOS processes where the number of metal layers will be higher and the insulator thickness larger.

Experiments

Different wafers have been fabricated and measured. All wafers were made starting from a HR Silicon substrate, i.e. substrates having a resistivity of about 10⁴ Ω.cm or higher. Table 1 hereinunder gives results for the fabricated wafers and some of their features. All wafers, except DLBHR26 and DLBHR26tb, were fabricated with a polysilicon layer deposited on a HR silicon substrate at different temperatures for different wafers, the deposited polysilicon layers having varying thickness for different wafers. In all cases, the polysilicon layer was deposited with a Low Pressure-Chemical-Vapour-Deposition (LPCVD) process. However the present invention is not limited to this process. Alternative deposition methods are e.g. Plasma-Enhanced Chemical Vapour Deposition (PECVD) or Atmospheric Pressure Chemical Vapour Deposition (APCVD). Wafers DLBHR26 and DLBHR26tb were both fabricated with an amorphous silicon layer deposited on a HR silicon substrate, according to an embodiment of the present invention. The silicon was then crystallized with a RTA during 2 min at 900° C. The rise time of the RTA temperature was 2 seconds to rise from ambient temperature (20° C.) to 900° C. One reference wafer, DLBH13, was also made without additional polysilicon layer. For all wafers, the insulating layer was then deposited with a Qₒₓ-rich, 3 μm-thick layer of Silicon dioxide through a PECVD process to demonstrate the efficiency of the additional polysilicon layer. It is expected and known from literature, though not measured, that the value of charge concentration Qₒₓ in the insulating layer is at least several times 10¹¹/cm² for such an oxide layer and that the trap density at the oxide-polysilicon interface is higher than 10¹¹/cm²/eV.

All wafers (except Leti 025 and ST 013) were then cut in two and one half was annealed at a temperature of 950° C. during 4 hours in a neutral ambient (atmospheric pressure, 100% N₂) to simulate the thermal budget of a standard semiconductor device processing. The extension ‘tb’ was added to the identification of these samples. The other half was not annealed. Finally, coplanar waveguides were patterned in a 1 μm—thick Aluminium layer deposited on the oxide layer. CPWs are typical transmission lines used in HF analog integrated circuits. They were used in these experiments to characterize the effective resistivity of the fabricated wafers.

For comparison purposes, CPW lines built on commercially available high resistivity SOI substrates (from SOITEC) and processed outside the inventors' laboratory were measured as well: CPW lines fabricated in a full SOI CMOS process at CEA-LETI (Leti 025) and at ST-M (ST 013). These results are shown in Table 1 as well.

TABLE 1

| | Si layer | Si layer | | Effective |
|---|---|---|---|---|
| | deposition | thickness | | resistivity |
| Wafer Id | T [° C.] | [nm] | Annealing | [Ω · cm] |
| DLBH13 | — | — | No | 200˜400 |
| DLBH13tb | — | — | Yes | NA |
| DLBHR14 | 585 | 20 | No | 300 |
| DLBHR14tb | 585 | 20 | Yes | 500 |
| DLBHR15 | 585 | 80 | No | 900 |
| DLBHR15tb | 585 | 80 | Yes | 5k |
| DLBHR16 | 585 | 150 | No | 1k |
| DLBHR16tb | 585 | 150 | Yes | >10k |
| DLBHR17 | 625 | 20 | No | 900 |
| DLBHR17tb | 625 | 20 | Yes | 7k |
| DLBHR18 | 625 | 80 | No | 1k |
| DLBHR18tb | 625 | 80 | Yes | 9k |
| DLBHR19 | 625 | 150 | No | 5k |
| DLBHR19tb | 625 | 150 | Yes | 9k |
| Leti 025 | — | — | — | 200˜250 |
| ST 013 | — | — | — | 600˜800 |
| DLBHR26 | 525 + RTA | 400 | No | >10k |
| DLBHR26tb | 525 + RTA | 400 | Yes | >10k |

The effective resistivity of wafer DLBHR13 (reference wafer without polysilicon layer at the substrate-insulating layer interface) is around 200 to 400 Ω.cm, indicating high ohmic losses into the silicon substrate. On the other hand, all HR silicon wafers containing an additional polysilicon layer underneath the passivated oxide layer, i.e. between the substrate and the insulating layer, present a higher effective resistivity, as can be seen from Table 1. Preferably, according to an embodiment of the present invention, the effective resistivity of a multilayer structure according to the present invention is not lower than 5 kΩ, still more preferred not lower than 10kΩ. It can be observed from table 1 above that the resulting effective resistivity depends on the polysilicon layer thickness, indicating that volume traps in the polysilicon layer play an important role. It has been demonstrated that a minimum polysilicon thickness of 200 nm can be considered to suppress the parasitic conduction layer at the oxide-silicon interface efficiently.

Measuring the effective resistivity of each sample before and after a long thermal annealing (4 hours) at 950° C. enabled the simulation of the effect of a CMOS thermal budget on the effective resistivity stability. The results clearly show that the thermal anneal has a strong effect on the effective resistivity of the wafers with deposited polysilicon, whereas no effect is observed in the case of amorphous silicon layer deposited at 525° C. and crystallized by Rapid Thermal Annealing (RTA) during 2 minutes at 900° C. (DLBR26 and DLBR26tb). The rise time of the RTA temperature was 2 seconds to rise from ambient temperature (20° C.) to 900° C.

The above suggests that only theses samples are thermodynamically stable. The effective resistivity for both these samples is higher than 10000 Ω.cm, which is by far a satisfactory value.

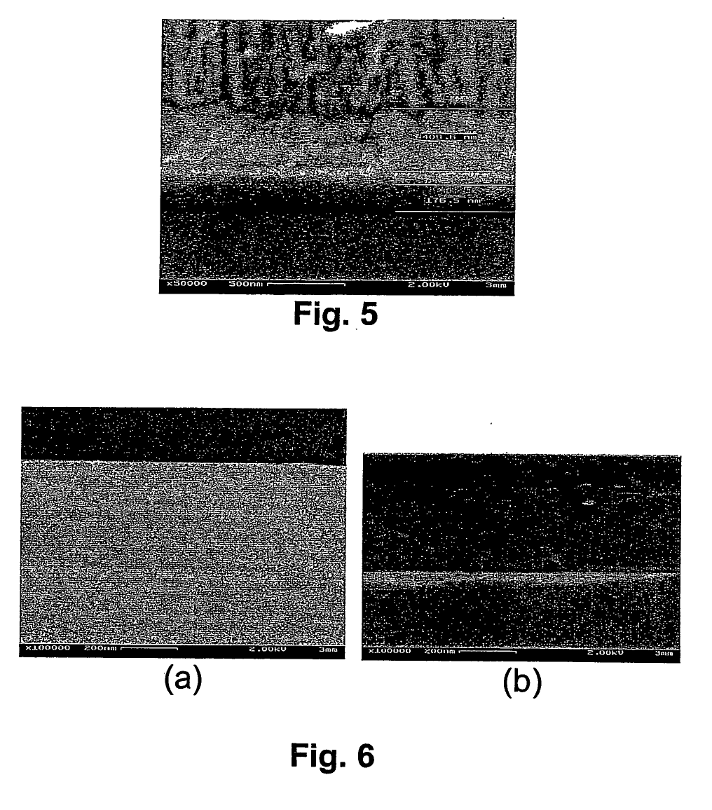

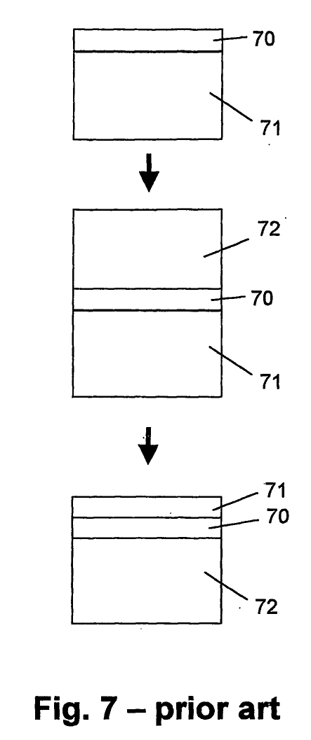

In order to check the bondability of each deposited polysilicon layer with future buried oxide of an SOI wafer, scanning electron microscope (SEM) pictures and SEM measurements were made. FIGS. 5 and 6 present, respectively, the cross-section of a polysilicon layer deposited at 625° C. and that of an RTA-crystallized silicon layer deposited at 525° C. The lower grain size and thus higher trap density in the case of the RTA-crystallized silicon layer deposited at 525° C. can be clearly seen. Moreover, the surface quality is by far better for that layer compared to classical polysilicon deposited at 625° C. Atomic force microscope (AFM) measurements performed on 2×2 μm² scan areas confirm these observations: RMS (root mean square) roughness/maximum height of 2.24 nm/16.5 nm and 0.37 nm 13.14 nm were measured for respectively the polysilicon at 625° C. and the RTA-crystallized silicon deposited at 525° C., as illustrated in the AFM pictures of FIGS. 11(b) and 11(a) respectively. For the latter, the quality of the surface will allow bonding without the use of Chemical Mechanical Polishing (CMP) of the surface. SEM pictures have determined that the size of the grains is 20 to 40 nm for the RTA-crystallized silicon deposited at 525° C., while it is 200 nm or more for polysilicon deposited at 625° C. Therefore, the best candidate for obtaining extremely high and stable resistivity multilayer wafers is the amorphous silicon layer deposited at low temperature, e.g. about 525° C., and crystallized by RTA at high temperature, e.g. 900° C. or higher.

It is to be understood that although preferred embodiments, specific constructions and configurations, as well as materials, have been discussed herein for devices according to the present invention, various changes or modifications in form and detail may be made without departing from the scope and spirit of this invention. For example, although a manufacturing method of the Smart Cut® type has been described, other methods for manufacturing multilayer structures can be used as well, in particular methods including bonding of substrates, methods of the ELTRAN type. Furthermore, although SOI has been described and discussed, the method of the present invention can also be used for manufacturing other multilayer stacks such as for example, but not limited to, Back Etched SOI (BESOI), Strained-Silicon-on-Silicon Germanium-on-Insulator (SGOI), Strained Silicon-on-Insulator (sSOI), Germanium-on-Insulator (GeOI), Silicon-on-Anything (SOA), or Silicon-on-Insulating Multilayers.

1-19. (canceled)

20. A method of manufacturing of a multilayer semiconductor structure comprising a high resistivity silicon substrate with resistivity higher than 3 kΩ.cm, an active semiconductor layer and an insulating layer in between the silicon substrate and the active semiconductor layer, wherein the method comprises suppressing ohmic losses inside the high resistivity silicon substrate by increasing charge trap density between the insulating layer and the silicon substrate.

21. A method according to claim 20, wherein increasing charge trap density comprises applying an intermediate layer in between the silicon substrate and the insulating layer, the intermediate layer comprising grains having a size, wherein the mean size of the grains of the intermediate layer is smaller than 150 nm, preferably smaller than 50 nm.

22. A method according to claim 21, wherein the intermediate layer has a charge trap density of at least 10¹¹/cm²/eV, preferably at least 10¹²/cm²/eV.

23. A method according to claim 21, wherein applying an intermediate layer comprises applying any of an undoped or lightly doped silicon layer, an undoped polysilicon layer, a germanium layer, an undoped polygermanium layer or a poly-SiGe silicon carbide layer in between the silicon substrate and the insulating layer.

24. A method according to claim 21, the intermediate layer having an RMS roughness, wherein the RMS roughness of the intermediate layer has an average value smaller than or equal to 0.5 nm.

25. A method according to claim 24, wherein applying a polysilicon layer comprises depositing amorphous silicon on the silicon substrate and crystallizing the amorphous silicon so as to form the polysilicon layer.

26. A method according to claim 25, wherein crystallizing comprises any of thermal annealing or rapid thermal annealing (RTA) or laser crystallisation.

27. A method according to claim 21, the method comprising bonding an intermediate layer-covered high resistivity silicon substrate to an insulator-passivated semiconductor substrate.

28. A method according to claim 27, the method comprising a surface oxidation of the intermediate layer prior to bonding the high resistivity silicon substrate to the insulator-passivated semiconductor substrate.

29. A method according to claim 21, the method comprising providing an intermediate layer on an insulator-passivated semiconductor substrate, and bonding this to a high-resistivity silicon substrate.

30. A method according to claim 21, wherein the intermediate layer has a layer thickness of at least 100 nm, preferably between 100 nm and 450 nm, more preferred between 200 nm and 300 nm.

31. A method according to claim 21, wherein the density of charge traps remains higher than or equal to 10¹¹/cm²/eV after a standard CMOS process is performed on the structure.

32. A multilayer structure comprising a high resistivity silicon substrate with a resistivity higher than 3 kΩ.cm, an active semiconductor layer and an insulating layer in between the silicon substrate and the active semiconductor layer, wherein the multilayer structure comprises an intermediate layer in between the high resistivity silicon substrate and the insulating layer, the intermediate layer comprising grains having a size, wherein the mean size of the grains of the intermediate layer is smaller than 150 nm, preferably smaller than 50 nm.

33. A multilayer structure according to claim 32, wherein the intermediate layer has a trap density of at least 10¹¹/cm²/eV, preferably at least 10¹²/cm²/eV.

34. A multilayer structure according to claim 32, wherein the multilayer structure has an effective resistivity higher than 5 kΩ.cm, preferably higher than 10 kΩ.cm.

35. A multilayer structure according to claim 32, wherein the intermediate layer comprises any of an undoped or lightly doped silicon layer, an undoped polysilicon layer, a germanium layer, an undoped polygermanium layer or a poly-SiGe silicon carbide layer.

36. A multilayer structure according to claim 32, wherein the intermediate layer has an RMS roughness with an average value smaller than or equal to 0.5 nm.

37. A multilayer structure according to claim 32, wherein the active semiconductor layer is made from at least one of Si, Ge, SiₓGe_{y}, SiC, InP, GaAs or GaN.

38. A multilayer structure according to claim 32, wherein the insulating layer is formed of at least one of an oxide, a nitride, Si₃N₄, a porous insulating material, a low-k insulating material, a high-k dielectric or a polymer.
